(19) United States
(12) Patent Application Publication
(10) Pub. No.: US 2025/0254839 A1
(43) Pub. Date: Aug. 7, 2025

(54) HEAT DISPENSING STRUCTURE FOR ELECTRIC DEVICE

(71) Applicant: Wistron NeWeb Corporation, Hsinchu (TW)

(72) Inventors: Tzu-Chun HUANG, Hsinchu (TW); Hsiang-Keng HSIEH, Hsinchu (TW); Ting CHEN, Hsinchu (TW); Yu-Shih LIN, Hsinchu (TW); Shih-Hang LIN, Hsinchu (TW); En-Yu YEH, Hsinchu (TW)

(21) Appl. No.: 19/019,661

(22) Filed: Jan. 14, 2025

(30) Foreign Application Priority Data
Feb. 5, 2024 (TW) 113104434

(51) Int. Cl. H05K 7/20

(52) U.S. Cl. CPC H05K 7/20454; H05K 7/2049

(57) ABSTRACT

A heat dispensing structure for an electric device includes an electric element, a heat dissipating unit opposite to the electric element along a first direction and an elastic heat dissipating structure located between the electric element and the heat dissipating unit along the first direction. The elastic heat dissipating structure includes a first elastic arm having a first fixed end and a first movable end and a second elastic arm having a second fixed end and a second movable end. The first and second fixed ends are fixedly connected to one of the electric element and the heat dissipating unit, and the first and second movable ends contact another one of the two. The first movable end and the second movable end are separated by a first distance before being pressed and by a second distance after being pressed, and the second distance is larger than the first distance.

### RELATED APPLICATIONS

This application claims priority to Taiwan Application Serial Number 113104434, filed Feb. 5, 2024, which is herein incorporated by reference.

### BACKGROUND

### Technical Field

The present disclosure relates to a heat dispensing structure. More particularly, the present disclosure relates to a heat dispensing structure for an electric device.

### Description of Related Art

With the advancement of technology, the number of electronic elements contained in modules has increased, and these electronic elements generate heat when powered, thus requiring heat dissipating units for cooling. Common heat dissipating units include heat pipes and heat sinks. Heat pipes can connect multiple electronic elements (heat sources) and heat sinks to achieve cooling. Multiple fixed points are set on the heat sink for the heat pipes, and there are often tolerances between the fixed points. Therefore, thermal interface materials such as thermal pads or thermal grease can be used to solve this problem. However, in some cases, such as when the tolerance is too large, the thermal grease cannot be used alone, and the thermal pads or a combination of the thermal pads and the thermal grease must be used.

The thermal pads can be placed between the heat dissipating unit and the electronic elements, and the compression of the thermal pads can absorb the tolerance. However, the thermal conductivity value of common thermal pads is up to 20 W/m-k, and the thickness needs to be 1 mm. Compared to the thermal grease with a thermal conductivity value of 5 W/m-k to 6 W/m-k and a material thickness close to 0 mm, the thermal effect of thermal pads is relatively poor.

In addition, spring screws are used to lock around the electronic elements, creating a spring pressure between the electronic elements and the heat dissipating unit, which can absorb tolerance. However, if the heat dissipating unit itself is made in the form of a casing, general screws must be used for locking. In the face of larger mechanical tolerances, thicker thermal pads or additional metal blocks are required to absorb the tolerance, resulting in reduced heat transferring efficiency.

Some manufacturers have improved the heat dissipating unit itself, such as forming chunks with different heights on aluminum extruded heat sinks to match with thermal pads for absorbing tolerance. However, these chunks are generally processed using CNC, significantly increasing manufacturing costs.

In view of this, how to improve the heat dispensing structure of an electric device containing electronic elements and heat dissipating units to have convenient spatial configuration and higher thermal performance has become a goal for related industries.

### SUMMARY

According to one aspect of the present disclosure, a heat dispensing structure for an electric device includes an electric element, a heat dissipating unit, and an elastic heat dissipating structure. The heat dissipating unit is opposite to the electric element along a first direction. The elastic heat dissipating structure is disposed between the electric element and the heat dissipating unit along the first direction. The elastic heat dissipating structure includes a first elastic arm and a second elastic arm. The first elastic arm includes a first fixed end and a first movable end opposite to each other along the first direction. The second elastic arm includes a second fixed end and a second movable end opposite to each other along the first direction. The first fixed end and the second fixed end are fixedly connected to one of the electric element and the heat dissipating unit, and the first movable end and the second movable end contact another one of the electric element and the heat dissipating unit. When the elastic heat dissipating structure is subjected to a pressure in the first direction, the first movable end and the second movable end are allowed to move in a second direction. The first movable end and the second movable end are separated by a first distance before being pressed and by a second distance after being pressed, and the second distance is greater than the first distance.

According to another aspect of the present disclosure, a heat dispensing structure for an electric device includes an electric element, a heat dissipating unit, and an elastic heat dissipating structure. The heat dissipating unit is opposite to the electric element along a first direction. The elastic heat dissipating structure is disposed between the electric element and the heat dissipating unit along the first direction. The elastic heat dissipating structure includes a plurality of first elastic arms and a plurality of second elastic arms. Each of the plurality of first elastic arms includes a first fixed end and a first movable end opposite to each other along the first direction. Each of the plurality of second elastic arms includes a second fixed end and a second movable end opposite to each other along the first direction. The first fixed ends and the second fixed ends are fixed to one of the electric element and the heat dissipating unit, and the first movable ends and the second movable ends contact another one of the electric element and the heat dissipating unit. When the elastic heat dissipating structure is subjected to a pressure in the first direction, one of the first movable ends nearest to the second movable ends and one of the second movable ends nearest to the first movable ends are allowed to move away from each other in a second direction.

### BRIEF DESCRIPTION OF THE DRAWINGS

The disclosure can be more fully understood by reading the following detailed description of the embodiments, with reference made to the accompanying drawings as follows:

FIG. 1 is a front schematic view of a heat dispensing structure for an electric device according to a first embodiment of the present disclosure.

FIG. 2 is a perspective schematic view of an elastic heat dissipating structure of the heat dispensing structure in FIG. 1.

FIG. 3 is an assembling operation diagram of the heat dispensing structure in FIG. 1.

FIG. 4 is a front schematic view of a heat dispensing structure for an electric device according to a second embodiment of the present disclosure.

FIG. 5 is a perspective schematic view of a first elastic arm and a second elastic arm of a heat dispensing structure for an electric device according to a third embodiment of the present disclosure.

FIG. 6 is a sectional schematic view of a first elastic arm and a second elastic arm connected to a substrate in a heat dispensing structure for an electric device according to a fourth embodiment of the present disclosure.

FIG. 7 is a front schematic view of a heat dissipating unit and an elastic heat dissipating structure of a heat dispensing structure for an electric device according to a fifth embodiment of the present disclosure.

FIG. 8 is a perspective schematic view of an elastic heat dissipating structure of a heat dispensing structure for an electric device according to a sixth embodiment of the present disclosure.

FIG. 9 is a partial front schematic view of a first elastic arm and a second elastic arm of a heat dispensing structure for an electric device according to a seventh embodiment of the present disclosure.

FIG. 10 is a front schematic view of an elastic heat dissipating structure of a heat dispensing structure for an electric device according to an eighth embodiment of the present disclosure.

FIG. 11 is a front schematic view of an elastic heat dissipating structure of a heat dispensing structure for an electric device according to a ninth embodiment of the present disclosure.

### DETAILED DESCRIPTION

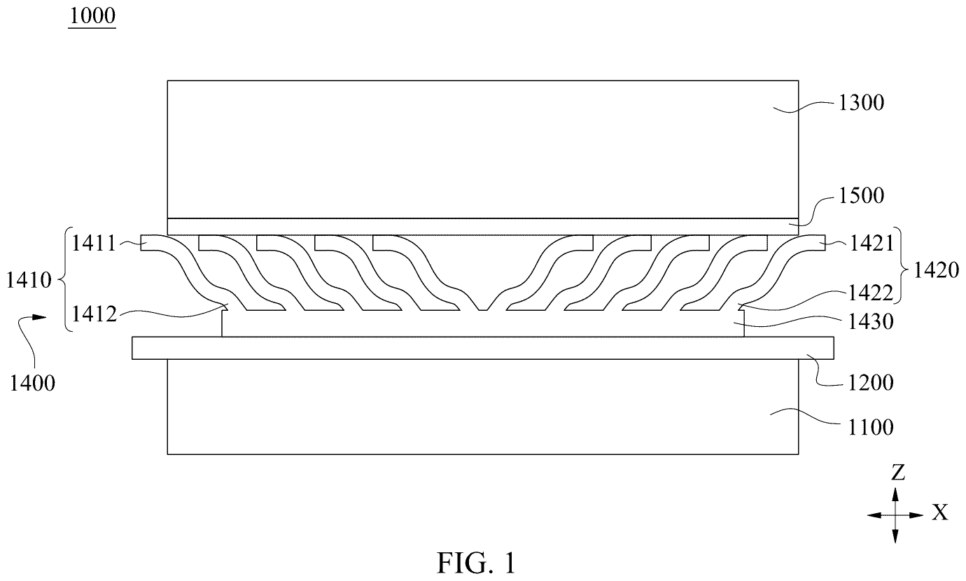

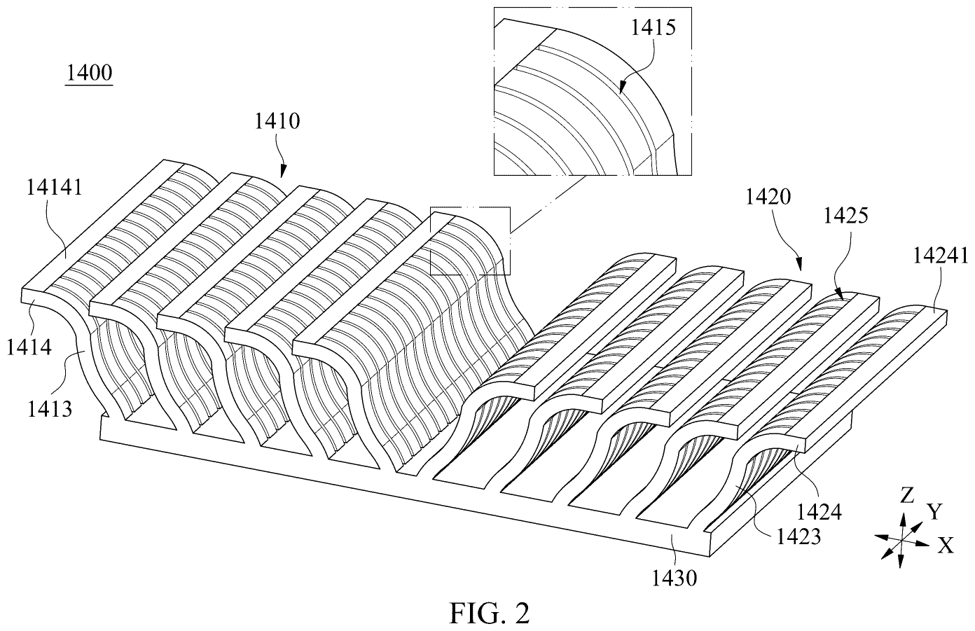

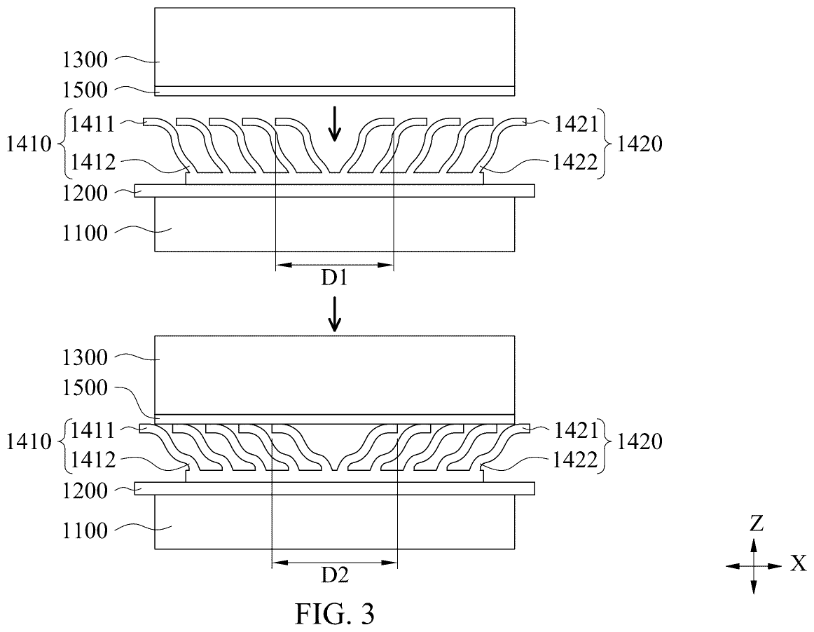

Please refer to FIG. 1, FIG. 2, and FIG. 3, where FIG. 1 is a front schematic view of a heat dispensing structure 1000 for an electric device according to a first embodiment of the present disclosure, FIG. 2 is a perspective schematic view of an elastic heat dissipating structure 1400 of the heat dispensing structure 1000 in FIG. 1, and FIG. 3 is an assembling operation diagram of the heat dispensing structure 1000 in FIG. 1. The heat dispensing structure 1000 includes an electric element 1100, a heat dissipating unit 1300, and the elastic heat dissipating structure 1400.

The heat dissipating unit 1300 is opposite to the electric element 1100 along a first direction (parallel to the Z-axis). The elastic heat dissipating structure 1400 is disposed between the electric element 1100 and the heat dissipating unit 1300 along the first direction. The elastic heat dissipating structure 1400 includes a first elastic arm 1410 and a second elastic arm 1420. The first elastic arm 1410 includes a first movable end 1411 and a first fixed end 1412 opposite to each other along the first direction. The second elastic arm 1420 includes a second movable end 1421 and a second fixed end 1422 opposite to each other along the first direction. The first fixed end 1412 and the second fixed end 1422 are fixedly connected to one of the electric element 1100 and the heat dissipating unit 1300 (indirectly fixed to the electric element 1100 in the first embodiment), and the first movable end 1411 and the second movable end 1421 contact the other one of the electric element 1100 and the heat dissipating unit 1300 (indirectly contact the heat dissipating unit 1300 in the first embodiment). When the elastic heat dissipating structure 1400 is subjected to a pressure in the first direction, the first movable end 1411 and the second movable end 1421 are allowed to move in a second direction (parallel to the X-axis). The first movable end 1411 and the second movable end 1421 are separated by a first distance D1 before being pressed and by a second distance D2 after being pressed, where the second distance D2 is greater than the first distance D1. The first direction is different from the second direction, and in this embodiment, the first direction corresponds to the vertical direction, and the second direction corresponds to the longitudinal direction.

Therefore, the first elastic arm 1410 and the second elastic arm 1420 can deform after being pressed, absorbing the tolerance between the electric element 1100 and the heat dissipating unit 1300. The details of the heat dispensing structure 1000 will be described later.

The electric element 1100 can be disposed on a circuit board 1200. The electric element 1100 generates heat when powered, and the heat can be transferred to the heat dissipating unit 1300 through the elastic heat dissipating structure 1400. The heat dissipating unit 1300 can include heat sinks and heat pipes, and the example in FIG. 1 is a heat sink, but the present disclosure is not limited thereto.

In the elastic heat dissipating structure 1400, the first elastic arm 1410 and the second elastic arm 1420 can be made of thin sheets of elastic and high thermal conductivity material. The first elastic arm 1410 and the second elastic arm 1420 can be curved or include bends, providing spring-like repeated compression and rebound capability. The first elastic arm 1410 and the second elastic arm 1420 can be made of metal material, and the thermal conductivity of the metal material can be above 250 W/m-k, preferably between 300 W/m-k and 450 W/m-k. In the first embodiment, the metal material is copper with a thermal conductivity of 391 W/m-k. Moreover, the thickness of the first elastic arm 1410 and the second elastic arm 1420 can be at least 0.1 mm, and in the first embodiment, the thickness is 0.4 mm, with thermal conductivity close to a thermal pad with a thermal conductivity of 20 W/m-k and a thickness of 1 mm.

The elastic heat dissipating structure 1400 can further include a substrate 1430. The first fixed end 1412 and the second fixed end 1422 can be connected to the substrate 1430. In the first embodiment shown in FIG. 1, the first fixed end 1412 and the second fixed end 1422 are integrally connected to the substrate 1430. Therefore, the substrate 1430 can be soldered to the circuit board 1200, indirectly fixing the first fixed end 1412 and the second fixed end 1422 to the electric element 1100. In other embodiments, the substrate can be directly fixed to the heat dissipating unit, and the present disclosure is not limited thereto.

As shown in FIG. 1 and FIG. 2, the first elastic arm 1410 can further include a first body portion 1413 and a first plate portion 1414. The first plate portion 1414 extends from a distal end of the first body portion 1413 in the second direction and includes a first contact plane 14141. The first body portion 1413 is adjacent to the electric element 1100, and the first contact plane 14141 contacts the heat dissipating unit 1300. The second elastic arm 1420 further includes a second body portion 1423 and a second plate portion 1424. The second plate portion 1424 extends from a distal end of the second body portion 1423 in the second direction and includes a second contact plane 14241. The second body portion 1423 is adjacent to the electric element 1100, and the second contact plane 14241 contacts the heat dissipating unit 1300. The second plate portion 1424 and the first plate portion 1414 extend in opposite directions (the second plate portion 1424 extends in the opposite direction to the first plate portion 1414 along the X-axis). Further, the first body portion 1413 has a first inclined direction, the second body portion 1423 has a second inclined direction, and the first inclined direction is different from the second inclined direction.

Specifically, the first body portion 1413 extends integrally from the substrate 1430 in the first direction and is curved. The proximal end of the first body portion 1413 can be defined as the first fixed end 1412, and the portion of the first plate portion 1414 that contacts the heat dissipating unit 1300 can be defined as the first movable end 1411. Similarly, the second body portion 1423 extends integrally from the substrate 1430 in the first direction and is curved. The proximal end of the second body portion 1423 can be defined as the second fixed end 1422, and the portion of the second plate portion 1424 that contacts the heat dissipating unit 1300 can be defined as the second movable end 1421. It is particularly noted that in the first embodiment, since the first fixed end 1412 and the second fixed end 1422 are fixedly connected to the electric element 1100 and cannot move in the second direction relative to the electric element 1100, they are called fixed ends, not the ends connected to the substrate 1430. In other embodiments, the first fixed end and the second fixed end can be directly soldered to one of the electric element and the heat dissipating unit, and the first movable end and the second movable end are respectively connected to two substrates, and the two substrates are not soldered to the other one of the electric element and the heat dissipating unit, allowing the two substrates to move away from each other after being pressed, making the second distance between the first movable end and the second movable end greater than the first distance before being pressed. Additionally, when there are a plurality of first elastic arms and second elastic arms, only the second distance between the nearest first elastic arm and the nearest second elastic arm needs to be greater than the first distance, and the present disclosure is not limited thereto.

In the first embodiment, the elastic heat dissipating structure 1400 includes a plurality of first elastic arms 1410 and a plurality of second elastic arms 1420. Assuming the substrate 1430 includes a midline in the second direction, the plurality of first elastic arms 1410 are arranged at intervals on the left side of the midline (i.e., the left half of FIG. 1), and the plurality of second elastic arms 1420 are arranged at intervals on the right side of the midline (i.e., the right half of FIG. 1), and the first elastic arm 1410 and the second elastic arm 1420 that are nearest to the midline form a V-shape in the X-axis and Z-axis plane.

The first elastic arm 1410 can further include a plurality of first cut grooves 1415. The plurality of first cut grooves 1415 penetrate the first body portion 1413 along the second direction and are arranged along a third direction (parallel to the Y-axis) to divide the first elastic arm 1410 into a plurality of first elastic ribs. The second elastic arm 1420 includes a plurality of second cut grooves 1425. The plurality of second cut grooves 1425 penetrate the second body portion 1423 along the second direction and are arranged along the third direction to divide the second elastic arm 1420 into a plurality of second elastic ribs. The third direction can be different from the first direction and the second direction.

Specifically, as shown in FIG. 2, the first elastic arm 1410 and the second elastic arm 1420 are thin sheet structures with thickness in the second direction and width in the third direction. The first cut grooves 1415 penetrate the first body portion 1413, but the first plate portion 1414 is not fully penetrated or only partially penetrated, and the proximal end of the first body portion 1413 is connected to the substrate 1430, forming interconnected and continuous first elastic ribs. Similarly, the second elastic arm 1420 forms interconnected and continuous second elastic ribs through the second cut grooves 1425. The configuration of the first cut grooves 1415 and the second cut grooves 1425 can help improve the flexibility of the first elastic arm 1410 and the second elastic arm 1420.

As shown in FIG. 3, during assembly, the first fixed end 1412 and the second fixed end 1422 can be fixed to the electric element 1100 through the substrate 1430, and thermal grease 1500 can be applied to the surface of the heat dissipating unit 1300 facing the elastic heat dissipating structure 1400. When the heat dissipating unit 1300 is pressed against the first elastic arm 1410 and the second elastic arm 1420, the first fixed end 1412 and the second fixed end 1422 are fixed and cannot move. The first elastic arm 1410 and the second elastic arm 1420, having elasticity, can deform. Through the V-shaped configuration in the X-axis and Z-axis plane, the first movable end 1411 moves to the left side of FIG. 3, and the second movable end 1421 moves to the right side of FIG. 3. Thus, the second distance D2 between the first movable end 1411 and the second movable end 1421 after being pressed is greater than the first distance D1 between the first movable end 1411 and the second movable end 1421 before being pressed. As a result, even with the presence of a tolerance, the bending condition of the first movable end 1411 and the second movable end 1421 can vary with the tolerance, adapting to different tolerances. Additionally, the high thermal conductivity of the elastic heat dissipating structure 1400 can aid in heat transfer, thereby transferring heat from the electric element 1100 to the heat dissipating unit 1300.

It should be particularly noted that the first contact plane 14141 of the first plate portion 1414 can help increase the contact area between the first elastic arm 1410 and the heat dissipating unit 1300 after being pressed, the second contact plane 14241 of the second plate portion 1424 can help increase the contact area between the second elastic arm 1420 and the heat dissipating unit 1300 after being pressed, and therefore heat dissipation is enhanced. The thermal grease 1500 can help reduce the friction between the first movable end 1411 and the second movable end 1421 and the surface of the heat dissipating unit 1300, as well as aid in heat dissipation. However, in other embodiments, it can be that the thermal grease is not applied. Additionally, in other embodiments, it can be that there is no substrate, and the first fixed end and the second fixed end may be directly fixed to the electric element, or the first fixed end and the second fixed end may be directly or indirectly fixed to the heat dissipating unit, and the first movable end and the second movable end may directly or indirectly contact the electric element, but the present disclosure is not limited thereto.

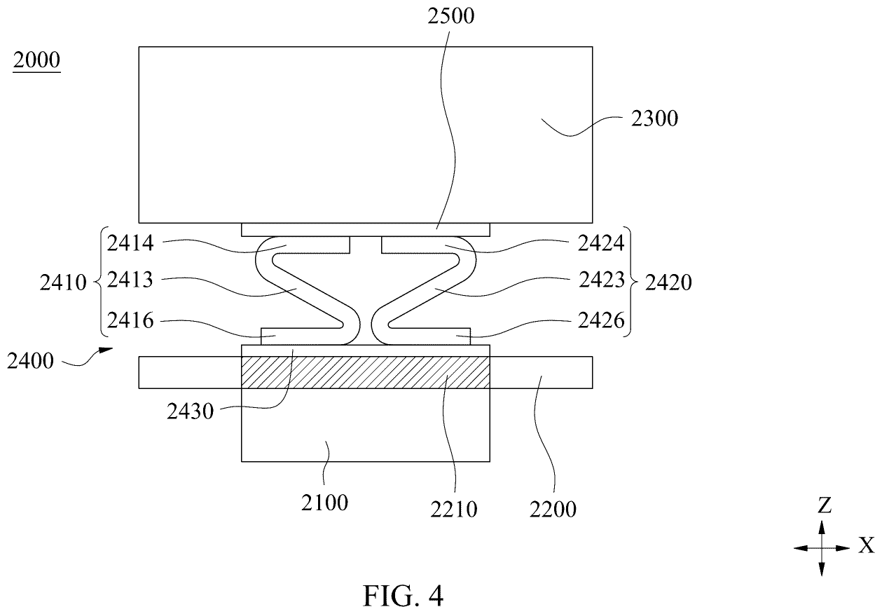

Please refer to FIG. 4, which is a front schematic view of a heat dispensing structure 2000 for an electric device according to a second embodiment of the present disclosure. The heat dispensing structure 2000 is similar to the heat dispensing structure 1000 in the first embodiment shown in FIG. 1, and includes an electric element 2100, a circuit board 2200, a heat dissipating unit 2300, an elastic heat dissipating structure 2400, and thermal grease 2500. However, the structure of the elastic heat dissipating structure 2400 is slightly different. Moreover, the circuit board 2200 may include conductive vias 2210, where the electric element 2100 is disposed at one end of the conductive vias 2210, and the elastic heat dissipating structure 2400 is disposed at the other end of the conductive vias 2210. Thus, the elastic heat dissipating structure 2400 can be soldered to the conductive vias 2210 using soldering paste, thereby indirectly fixing the elastic heat dissipating structure 2400 to the electric element 2100.

The first elastic arm 2410 may include a first base plate portion 2416. The first plate portion 2414 is connected to a distal end of the first body portion 2413, and the first base plate portion 2416 is connected to a proximal end of the first body portion 2413. The first base plate portion 2416 and the first plate portion 2414 extend in opposite directions. The second elastic arm 2420 may include a second base plate portion 2426. The second plate portion 2424 is connected to a distal end of the second body portion 2423, and the second base plate portion 2426 is connected to a proximal end of the second body portion 2423. The second plate portion 2424 and the second base plate portion 2426 extend in opposite directions.

Specifically, the first base plate portion 2416 is connected to the substrate 2430, for example, by soldering. The first base plate portion 2416, the first body portion 2413, and the first plate portion 2414 are integrally connected and form a left-right reversed “Z” shape. The first plate portion 2414 can contact the thermal grease 2500 and the heat dissipating unit 2300. Similarly, the second base plate portion 2426 is connected to the substrate 2430, for example, by soldering. The second base plate portion 2426, the second body portion 2423, and the second plate portion 2424 are integrally connected and form a “Z” shape. The second plate portion 2424 can contact the thermal grease 2500 and the heat dissipating unit 2300. Thus, when the heat dissipating unit 2300, the elastic heat dissipating structure 2400, and the electric element 2100 are assembled, the first body portion 2413 is inclined to the left side of FIG. 4, and the second body portion 2423 is inclined to the right side of FIG. 4, thereby increasing the first distance between the first movable end and the second movable end to the second distance. It should be particularly noted that although only a single first elastic arm 2410 and a single second elastic arm 2420 are illustrated in the second embodiment, multiple first elastic arms 2410 and multiple second elastic arms 2420 can be configured as in the first embodiment, and the present disclosure is not limited to the disclosure in the drawings.

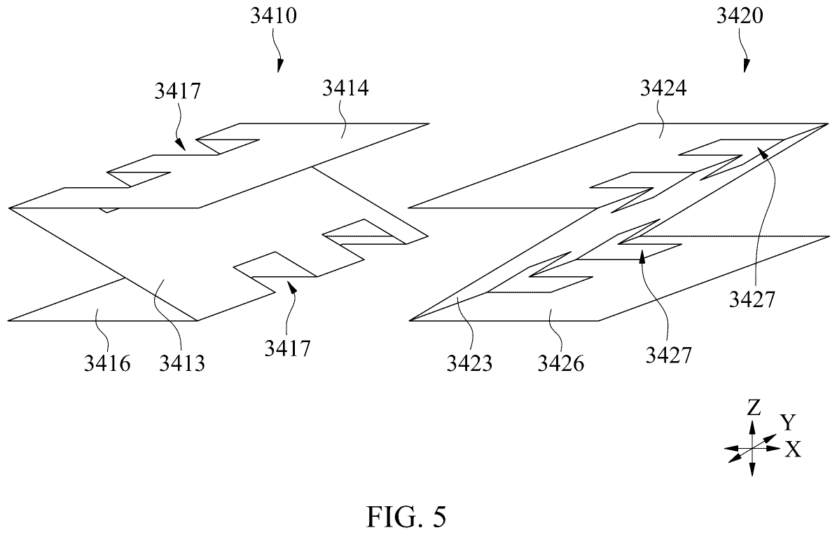

Please refer to FIG. 5, which is a perspective schematic view of a first elastic arm 3410 and a second elastic arm 3420 of a heat dispensing structure for an electric device according to a third embodiment of the present disclosure. The first elastic arm 3410 and the second elastic arm 3420 are similar to the first elastic arm 2410 and the second elastic arm 2420 in the second embodiment shown in FIG. 4, with thickness in the second direction and width in the third direction.

The first elastic arm 3410 further includes a plurality of first through holes 3417. A part of the plurality of first through holes 3417 are arranged along the third direction and penetrate a position where the first base plate portion 3416 and the first body portion 3413 connect in the second direction, and another part of the plurality of first through holes 3417 are arranged along the third direction and penetrate a position where the first plate portion 3414 and the first body portion 3413 connect in the second direction. The second elastic arm 3420 further includes a plurality of second through holes 3427. A part of the plurality of second through holes 3427 are arranged along the third direction and penetrate a position where the second base plate portion 3426 and the second body portion 3423 connect in the second direction, and another part of the plurality of second through holes 3427 are arranged along the third direction and penetrate a position where the second plate portion 3424 and the second body portion 3423 connect in the second direction.

As shown in FIG. 5, there are four first through holes 3417, two of which are located at the position where the first base plate portion 3416 and the first body portion 3413 are connected, and each of these two first through holes 3417 can be, for example, half located in the first base plate portion 3416 and half in the first body portion 3413, but the present disclosure is not limited thereto. The other two first through holes 3417 are located at the position where the first plate portion 3414 and the first body portion 3413 are connected, and each of these two first through holes 3417 can be, for example, half located in the first plate portion 3414 and half in the first body portion 3413, but the present disclosure is not limited thereto. Similarly, there are four second through holes 3427, two of which are located at a position where the second base plate portion 3426 and the second body portion 3423 are connected, and each of these two second through holes 3427 can be, for example, half located in the second base plate portion 3426 and half in the second body portion 3423, but the present disclosure is not limited thereto. The other two second through holes 3427 are located at a position where the second plate portion 3424 and the second body portion 3423 are connected, and each of these two second through holes 3427 can be, for example, half located in the second plate portion 3424 and half in the second body portion 3423, but the present disclosure is not limited thereto. Thus, the flexibility of the first elastic arm 3410 and the second elastic arm 3420 is increased. It is noted that for simplicity, FIG. 5 does not show the thickness of the first elastic arm 3410 and the second elastic arm 3420, but the present disclosure is not limited thereby.

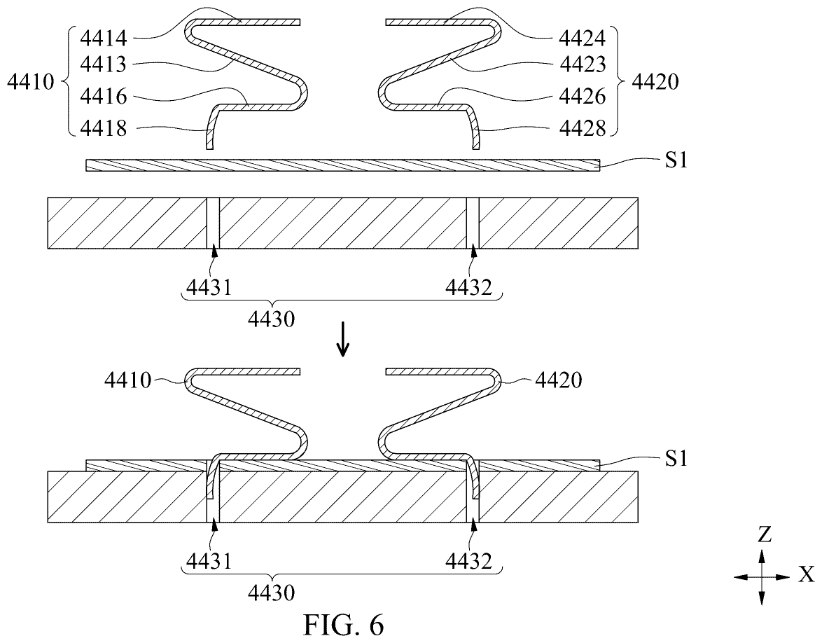

Please refer to FIG. 6, which illustrates a sectional schematic view of a first elastic arm 4410 and a second elastic arm 4420 connected to a substrate 4430 in a heat dispensing structure for an electric device according to a fourth embodiment of the present disclosure. The first elastic arm 4410 further includes a first protrusion 4418 located at the first fixed end, and the second elastic arm 4420 further includes a second protrusion 4428 located at the second fixed end. The substrate 4430 comprises a first groove 4431 and a second groove 4432 spaced apart in the second direction, the first protrusion 4418 is soldered to the first groove 4431, and the second protrusion 4428 is soldered to the second groove 4432.

Specifically, the first elastic arm 4410 is similar to the first elastic arm 2410 in the second embodiment shown in FIG. 4 and includes a first base plate portion 4416, a first body portion 4413, and a first plate portion 4414 integrally connected. The proximal end of the first base plate portion 4416 can be defined as the first fixed end, and it is integrally connected to the first protrusion 4418 extending in the first direction. The second elastic arm 4420 is similar to the second elastic arm 2420 in the second embodiment shown in FIG. 4 and includes a second base plate portion 4426, a second body portion 4423, and a second plate portion 4424 integrally connected. The proximal end of the second base plate portion 4426 can be defined as the first fixed end, and it is integrally connected to the second protrusion 4428 extending in the first direction. In the manufacturing process, solder paste S1 can be applied to the substrate 4430 first, then the first elastic arm 4410 can be positioned with its first protrusion 4418 in the first groove 4431, and the second elastic arm 4420 can be positioned with its second protrusion 4428 in the second groove 4432, followed by reflow soldering, thereby facilitating soldering by pre-fix the positions of the first elastic arm 4410 and the second elastic arm 4420.

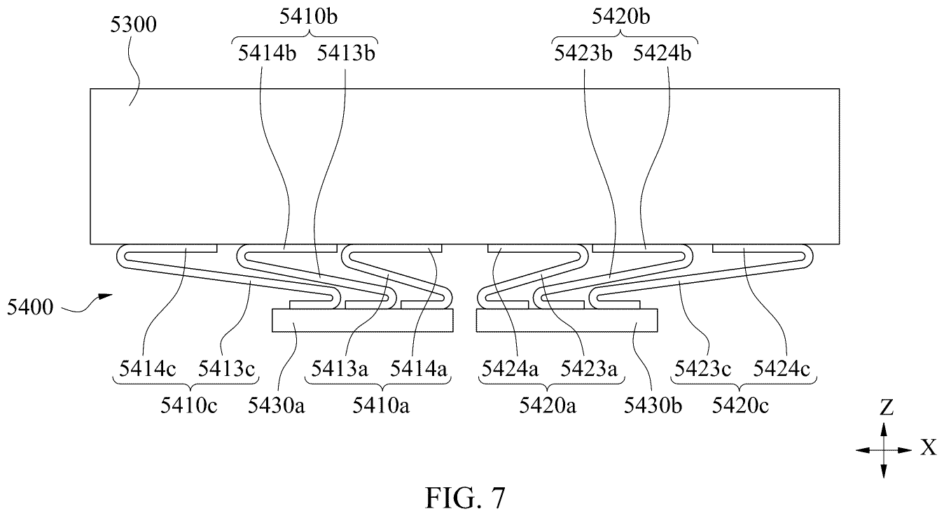

Please refer to FIG. 7, which is a front schematic view of a heat dissipating unit 5300 and an elastic heat dissipating structure 5400 of a heat dispensing structure for an electric device according to a fifth embodiment of the present disclosure. The elastic heat dissipating structure 5400 includes a first substrate 5430a, a second substrate 5430b, a plurality of first elastic arms 5410a, 5410b, 5410c, and a plurality of second elastic arms 5420a, 5420b, 5420c. First fixed ends of the first elastic arms 5410a, 5410b, 5410c are connected to the first substrate 5430a, and second fixed ends of the second elastic arms 5420a, 5420b, 5420c are connected to the second substrate 5430b.

Each of the first elastic arms 5410a, 5410b, 5410c includes a first body portion 5413a, 5413b, 5413c, and a first plate portion 5414a, 5414b, 5414c. Each of the first body portions 5413a, 5413b, 5413c includes a first body length, and the first body lengths are different. One of the first body portions 5413a, 5413b, 5413c nearest to the second elastic arms 5420a, 5420b, 5420c (in this case, the first body portion 5413a) has a first body length smaller than the first body length of one of the first body portions 5413a, 5413b, 5413c farthest from the second elastic arms 5420a, 5420b, 5420c (in this case, the first body portion 5413c).

Each of the second elastic arms 5420a, 5420b, 5420c includes a second body portion 5423a, 5423b, 5423c, and a second plate portion 5424a, 5424b, 5424c. Each of the second body portions 5423a, 5423b, 5423c includes a second body length, and the second body lengths are different. One of the second body portions 5423a, 5423b, 5423c nearest to the first elastic arms 5410a, 5410b, 5410c (in this case, the second body portion 5423a) has a second body length smaller than the second body length of one of the second body portions 5423a, 5423b, 5423c farthest from the first elastic arms 5410a, 5410b, 5410c (in this case, the second body portion 5423c).

In other embodiments, each first plate portion includes a first plate length, and the first plate lengths of the plurality of first plate portions are different. The first plate length of the first plate portion nearest to the second elastic arm (similar to the first plate portion 5414a in FIG. 7) is smaller than the first plate length of the first plate portion farthest from the second elastic arm (similar to the first plate portion 5414c in FIG. 7). Each second plate portion includes a second plate length, and the second plate lengths of the plurality of second plate portions are different. The second plate length of the second plate portion nearest to the first elastic arm (similar to the second plate portion 5424a in FIG. 7) is smaller than the second plate length of the second plate portion farthest from the first elastic arm (similar to the second plate portion 5424c in FIG. 7).

In other words, the shapes of the plurality of first elastic arms 5410a, 5410b, 5410c are similar, but the sizes of the first body portions 5413a, 5413b, 5413c may differ. The overall size of the first elastic arm 5410a is the smallest, the first body portion 5413c of the first elastic arm 5410c is the longest, and the inclination of the first body portion 5413c is the steepest. Similarly, the shapes of the plurality of second elastic arms 5420a, 5420b, 5420c are similar, but the sizes of the second body portions 5423a, 5423b, 5423c may differ. The overall size of the second elastic arm 5420a is the smallest, the second body portion 5423c of the second elastic arm 5420c is the longest, and the inclination of the second body portion 5423c is the steepest. Additionally, in other embodiments, the lengths of the first plate portion and the second plate portion may also differ. Thus, the contact area with the heat dissipating unit will increase, thereby enhancing the heat dissipation capability, without being limited by the size of the electric element.

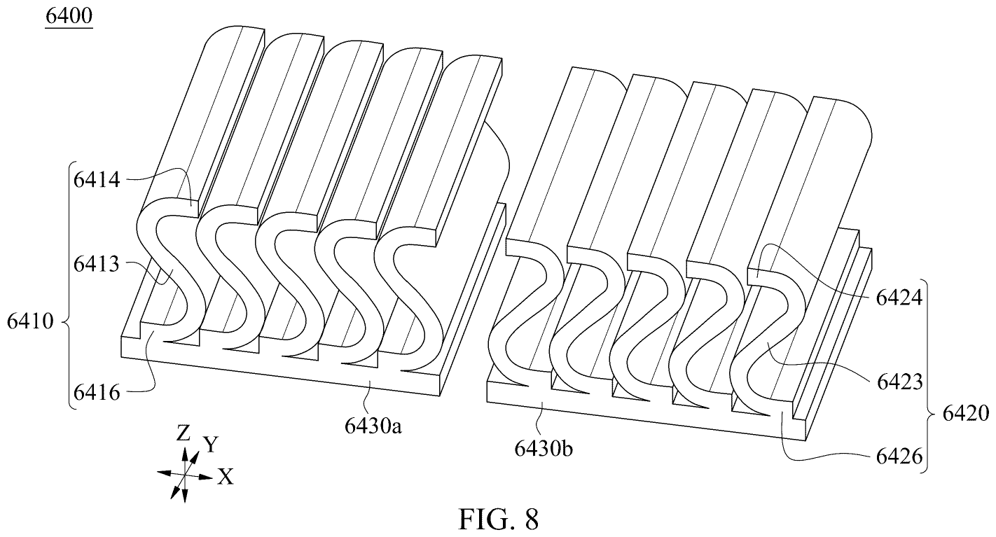

Please refer to FIG. 8, which is a perspective schematic view of an elastic heat dissipating structure 6400 of a heat dispensing structure for an electric device according to a sixth embodiment of the present disclosure. The elastic heat dissipating structure 6400 includes a first substrate 6430a, a second substrate 6430b, a plurality of first elastic arms 6410, and a plurality of second elastic arms 6420.

Each first elastic arm 6410 includes a first plate portion 6414, a first body portion 6413, and a first base plate portion 6416 integrally connected to form a first curved shape. Each second elastic arm 6420 includes a second plate portion 6424, a second body portion 6423, and a second base plate portion 6426 integrally connected to form a second curved shape, with the second curved shape being a mirror image of the first curved shape.

Specifically, each first elastic arm 6410 includes a first base plate portion 6416 connected to the first substrate 6430a, and the first curved shape forms an “S” shape. Each second elastic arm 6420 includes a second base plate portion 6426 connected to the second substrate 6430b, and the second curved shape forms a left-right reversed “S” shape, which is a mirror image of the first curved shape. The first substrate 6430a and the second substrate 6430b are soldered to the electric element or the heat dissipating unit. In other embodiments, the first base plate portion may be connected to the first substrate, forming an “S” shape, and the second base plate portion may be connected to the second substrate, forming a left-right reversed “S” shape, with the first base plate portion and the second base plate portion directly soldered to the electric element or the heat dissipating unit, where the first substrate and the second substrate can move away from each other after being pressed. Alternatively, the first base plate portion is connected to a first substrate and the second base plate portion is connected to a second substrate, the first plate portion is connected to a third substrate, and the second plate portion is connected to a fourth substrate. The first base plate portion and the second base plate portion are directly soldered to the electric element or the heat dissipating unit, and the third substrate and the fourth substrate can move away from each other after being pressed. The present disclosure is not limited thereby.

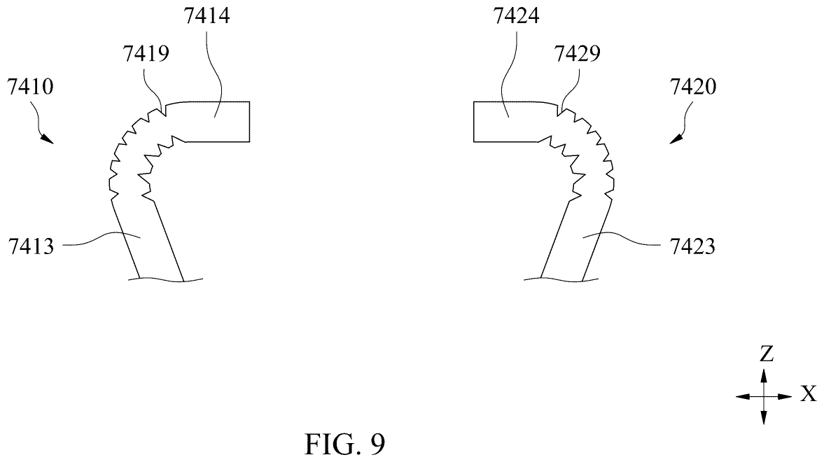

Please refer to FIG. 9, which is a partial front schematic view of a first elastic arm 7410 and a second elastic arm 7420 of a heat dispensing structure for an electric device according to a seventh embodiment of the present disclosure. The first elastic arm 7410 and the second elastic arm 7420 are similar to the first elastic arm 6410 and the second elastic arm 6420 in the sixth embodiment shown in FIG. 8, but the first elastic arm 7410 may further include a plurality of first notches 7419, and the second elastic arm 7420 may further include a plurality of second notches 7429. The plurality of first notches 7419 are disposed at a position where the first body portion 7413 is adjacent to the first plate portion 7414, and the plurality of second notches 7429 are disposed at a position where the second body portion 7423 is adjacent to the second plate portion 7424. The configuration of the first notches 7419 and the second notches 7429 can help improve the flexibility of the first elastic arm 7410 and the second elastic arm 7420.

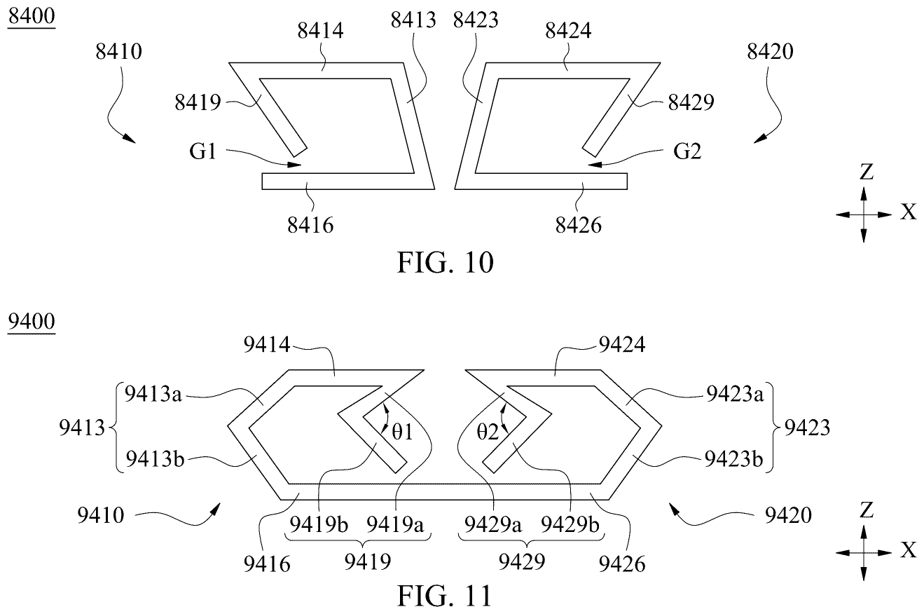

Please refer to FIG. 10, which is a front schematic view of an elastic heat dissipating structure 8400 of a heat dispensing structure for an electric device according to an eighth embodiment of the present disclosure. The elastic heat dissipating structure 8400 includes a first elastic arm 8410 and a second elastic arm 8420. The first elastic arm 8410 includes a first support portion 8419, which extends from one end of the first plate portion 8414 away from the first body portion 8413 toward the first base plate portion 8416. When the elastic heat dissipating structure 8400 is not being pressed, a gap G1 is formed between the first support portion 8419 and the first base plate portion 8416. When the elastic heat dissipating structure 8400 is being pressed, the first support portion 8419 contacts the first base plate portion 8416. The second elastic arm 8420 includes a second support portion 8429, which extends from one end of the second plate portion 8424 away from the second body portion 8423 toward the second base plate portion 8426. When the elastic heat dissipating structure 8400 is not being pressed, another gap G2 is formed between the second support portion 8429 and the second base plate portion 8426. When the elastic heat dissipating structure 8400 is being pressed, the second support portion 8429 contacts the second base plate portion 8426.

Specifically, the first base plate portion 8416, the first body portion 8413, the first plate portion 8414, and the first support portion 8419 are integrally connected to form a quadrilateral shape. The first body portion 8413 and the first support portion 8419 are both inclined, but the first support portion 8419 has a shorter length in the first direction and does not contact the first base plate portion 8416. Similarly, the second base plate portion 8426, the second body portion 8423, the second plate portion 8424, and the second support portion 8429 are integrally connected to form a quadrilateral shape. The second body portion 8423 and the second support portion 8429 are both inclined, but the second support portion 8429 has a shorter length in the first direction and does not contact the second base plate portion 8426. Since the first elastic arm 8410 and the second elastic arm 8420 are elastic, when the elastic heat dissipating structure 8400 is pressed in the first direction, the first body portion 8413, the first support portion 8419, the second body portion 8423, and the second support portion 8429 will become more inclined. This will cause the gaps G1 and G2 to disappear, and the first support portion 8419 and the second support portion 8429 will respectively contact the first base plate portion 8416 and the second base plate portion 8426. This not only helps support the first elastic arm 8410 and the second elastic arm 8420, but also helps transfer heat through the first support portion 8419 and the second support portion 8429 to the first plate portion 8414 and the second plate portion 8424, thereby enhancing the heat dissipation effect.

Please refer to FIG. 11, which is a front schematic view of an elastic heat dissipating structure 9400 of a heat dispensing structure for an electric device according to a ninth embodiment of the present disclosure. The elastic heat dissipating structure 9400 includes a first elastic arm 9410 and a second elastic arm 9420. The first elastic arm 9410 includes, in sequential connection, a first base plate portion 9416, a first body portion 9413, a first plate portion 9414, and a first support portion 9419. The second elastic arm 9420 includes, in sequential connection, a second base plate portion 9426, a second body portion 9423, a second plate portion 9424, and a second support portion 9429.

As shown in FIG. 11, one end of the first base plate portion 9416 away from the first body portion 9413 is connected to one end of the second base plate portion 9426 away from the second body portion 9423. The first support portion 9419 and the second support portion 9429 are positioned between the first body portion 9413 and the second body portion 9423 along the second direction. That is, the first base plate portion 9416 is connected to the second base plate portion 9426, and from left to right in FIG. 11, they are sequentially the first body portion 9413, the first support portion 9419, the second support portion 9429, and the second body portion 9423.

The first support portion 9419 may include a first upper section 9419a and a first lower section 9419b, which are connected to each other and form a first angle θ1. The second support portion 9429 includes a second upper section 9429a and a second lower section 9429b, which are connected to each other and form a second angle θ2, with the second angle θ2 facing the first angle θ1.

Specifically, the first body portion 9413 may also include a first upper half 9413a and a first lower half 9413b, which are connected to each other and form a first included angle. The second body portion 9423 may also include a second upper half 9423a and a second lower half 9423b, which are connected to each other and form a second included angle. Thus, the first upper half 9413a and the first lower half 9413b can be bent to match the bending of the first upper section 9419a and the first lower section 9419b, and the second upper half 9423a and the second lower half 9423b can be bent to match the bending of the second upper section 9429a and the second lower section 9429b. The first elastic arm 9410 and the second elastic arm 9420 are mirror images of each other, so the first angle θ1 can face the second angle θ2.

Since the first elastic arm 9410 and the second elastic arm 9420 are elastic, after being pressed, the first upper half 9413a and the first lower half 9413b bend more, the first upper section 9419a and the first lower section 9419b bend more, the second upper half 9423a and the second lower half 9423b bend more, and the second upper section 9429a and the second lower section 9429b bend more. This reduces the first included angle, the second included angle, the first angle θ1, and the second angle θ2. The first lower section 9419b of the first support portion 9419 and the second lower section 9429b of the second support portion 9429 respectively contact the first base plate portion 9416 and the second base plate portion 9426. This not only helps support the first elastic arm 9410 and the second elastic arm 9420 but also helps transfer heat through the first support portion 9419 and the second support portion 9429 to the first plate portion 9414 and the second plate portion 9424, thereby enhancing the heat dissipation effect.

From the above embodiments, it can be seen that the configuration of the elastic heat dissipating structure can use elasticity to absorb tolerance, and the good thermal conductivity of the elastic heat dissipating structure can also help improve the heat dissipation effect.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A heat dispensing structure for an electric device, comprising:
an electric element;
a heat dissipating unit, opposite to the electric element along a first direction; and
an elastic heat dissipating structure, disposed between the electric element and the heat dissipating unit along the first direction, the elastic heat dissipating structure comprising a first elastic arm and a second elastic arm, the first elastic arm comprising a first fixed end and a first movable end opposite to each other along the first direction, the second elastic arm comprising a second fixed end and a second movable end opposite to each other along the first direction, the first fixed end and the second fixed end being fixedly connected to one of the electric element and the heat dissipating unit, and the first movable end and the second movable end contacting another one of the electric element and the heat dissipating unit;
wherein, when the elastic heat dissipating structure is subjected to a pressure in the first direction, the first movable end and the second movable end are allowed to move in a second direction, the first movable end and the second movable end are separated by a first distance before being pressed and by a second distance after being pressed, and the second distance is greater than the first distance.

2. The heat dispensing structure of claim 1, wherein the elastic heat dissipating structure further comprises a substrate, and the first fixed end and the second fixed end are connected to the substrate.

3. The heat dispensing structure of claim 2, wherein the first fixed end and the second fixed end are integrally connected to the substrate.

4. The heat dispensing structure of claim 2, wherein the first elastic arm further comprises a first protrusion located at the first fixed end, the second elastic arm further comprises a second protrusion located at the second fixed end, the substrate comprises a first groove and a second groove spaced apart in the second direction, the first protrusion is soldered to the first groove, and the second protrusion is soldered to the second groove.

5. The heat dispensing structure of claim 2, wherein the substrate is soldered to the one of the electric element and the heat dissipating unit.

6. The heat dispensing structure of claim 1, wherein the first elastic arm further comprises a first body portion and a first plate portion, the first plate portion extends from a distal end of the first body portion in the second direction and comprises a first contact plane, the first body portion is adjacent to the one of the electric element and the heat dissipating unit, and the first contact plane contacts the another one of the electric element and the heat dissipating unit; the second elastic arm further comprises a second body portion and a second plate portion, the second plate portion extends from a distal end of the second body portion in the second direction and comprises a second contact plane, the second body portion is adjacent to the one of the electric element and the heat dissipating unit, and the second contact plane contacts the another one of the electric element and the heat dissipating unit; the second plate portion and the first plate portion extend opposite to each other.

7. The heat dispensing structure of claim 6, wherein the first body portion has a first inclined direction, and the second body portion has a second inclined direction, the first inclined direction being different from the second inclined direction.

8. The heat dispensing structure of claim 7, wherein the first elastic arm further comprises a plurality of first cut grooves, and the plurality of first cut grooves penetrate the first body portion along the second direction and are arranged along a third direction to divide the first elastic arm into a plurality of first elastic ribs; the second elastic arm further comprises a plurality of second cut grooves, and the plurality of second cut grooves penetrate the second body portion along the second direction and are arranged along the third direction to divide the second elastic arm into a plurality of second elastic ribs.

9. The heat dispensing structure of claim 6, wherein the first elastic arm further comprises a first base plate portion, the first base plate portion is connected to a proximal end of the first body portion, and the first base plate portion and the first plate portion extend opposite to each other; the second elastic arm further comprises a second base plate portion, the second base plate portion is connected to a proximal end of the second body portion, and the second base plate portion and the second plate portion extend opposite to each other.

10. The heat dispensing structure of claim 9, wherein the first elastic arm further comprises a plurality of first through holes, a part of the plurality of first through holes are arranged along a third direction and penetrate a position where the first base plate portion and the first body portion connect in the second direction, and another part of the plurality of first through holes are arranged along the third direction and penetrate a position where the first plate portion and the first body portion connect in the second direction; the second elastic arm further comprises a plurality of second through holes, a part of the plurality of second through holes are arranged along the third direction and penetrate a position where the second base plate portion and the second body portion connect in the second direction, and another part of the plurality of second through holes are arranged along the third direction and penetrate a position where the second plate portion and the second body portion connect in the second direction.

11. The heat dispensing structure of claim 9, wherein the first plate portion, the first body portion, and the first base plate portion are integrally connected to form a first curved shape, and the second plate portion, the second body portion, and the second base plate portion are integrally connected to form a second curved shape, the second curved shape being a mirror image of the first curved shape.

12. The heat dispensing structure of claim 9, wherein the first elastic arm further comprises a first support portion, the first support portion extends from an end of the first plate portion away from the first body portion toward the first base plate portion, and when the elastic heat dissipating structure is not being pressed, a gap is formed between the first support portion and the first base plate portion, and when the elastic heat dissipating structure is being pressed, the first support portion contacts the first base plate portion; the second elastic arm further comprises a second support portion, the second support portion extends from an end of the second plate portion away from the second body portion toward the second base plate portion, and when the elastic heat dissipating structure is not being pressed, another gap is formed between the second support portion and the second base plate portion, and when the elastic heat dissipating structure is being pressed, the second support portion contacts the second base plate portion.

13. The heat dispensing structure of claim 12, wherein an end of the first base plate portion away from the first body portion is connected to an end of the second base plate portion away from the second body portion, and the first support portion and the second support portion are located between the first body portion and the second body portion along the second direction.

14. The heat dispensing structure of claim 13, wherein the first support portion comprises a first upper section and a first lower section, and the first upper section and the first lower section are connected to each other and form a first angle; the second support portion comprises a second upper section and a second lower section, and the second upper section and the second lower section are connected to each other and form a second angle, the second angle facing the first angle.

15. The heat dispensing structure of claim 6, wherein the first elastic arm further comprises a plurality of first notches, and the plurality of first notches are disposed at a position where the first body portion is adjacent to the first plate portion; the second elastic arm further comprises a plurality of second notches, and the plurality of second notches are disposed at a position where the second body portion is adjacent to the second plate portion.

16. The heat dispensing structure of claim 1, wherein the elastic heat dissipating structure further comprises a first substrate and a second substrate, the first fixed end is connected to the first substrate, and the second fixed end is connected to the second substrate.

17. A heat dispensing structure for an electric device, comprising:
an electric element;
a heat dissipating unit, opposite to the electric element along a first direction; and
an elastic heat dissipating structure, disposed between the electric element and the heat dissipating unit along the first direction, the elastic heat dissipating structure comprising a plurality of first elastic arms and a plurality of second elastic arms, each of the plurality of first elastic arms comprising a first fixed end and a first movable end opposite to each other along the first direction, each of the plurality of second elastic arms comprising a second fixed end and a second movable end opposite to each other along the first direction, the first fixed ends and the second fixed ends being fixed to one of the electric element and the heat dissipating unit, and the first movable ends and the second movable ends contacting another one of the electric element and the heat dissipating unit;
wherein, when the elastic heat dissipating structure is subjected to a pressure in the first direction, one of the first movable ends nearest to the second movable ends and one of the second movable ends nearest to the first movable ends are allowed to move away from each other in a second direction.

18. The heat dispensing structure of claim 17, wherein each of the plurality of first elastic arms further comprises a first body portion and a first plate portion, each of the first plate portions extends from a distal end of each of the first body portions in the second direction and comprises a first contact plane, each of the first body portions is adjacent to the one of the electric element and the heat dissipating unit, and each of the first contact planes contacts the another one of the electric element and the heat dissipating unit; each of the plurality of second elastic arms further comprises a second body portion and a second plate portion, each of the second plate portions extends from a distal end of each of the second body portions in the second direction and comprises a second contact plane, each of the second body portions is adjacent to the one of the electric element and the heat dissipating unit, and each of the second contact planes contacts the another one of the electric element and the heat dissipating unit; each of the second plate portions and each of the first plate portions extend opposite to each other.

19. The heat dispensing structure of claim 18, wherein each of the first body portions comprises a first body length, the first body lengths being different, and the first body length of the first body portion nearest to the plurality of second elastic arms is smaller than the first body length of the first body portion farthest from the plurality of second elastic arms; each of the second body portions comprises a second body length, the second body lengths being different, and the second body length of the second body portion nearest to the plurality of first elastic arms is smaller than the second body length of the second body portion farthest from the plurality of first elastic arms.

20. The heat dispensing structure of claim 19, wherein each of the first plate portions comprises a first plate length, the first plate lengths being different, and the first plate length of the first plate portion nearest to the plurality of second elastic arms is smaller than the first plate length of the first plate portion farthest from the plurality of second elastic arms; each of the second plate portions comprises a second plate length, the second plate lengths being different, and the second plate length of the second plate portion nearest to the plurality of first elastic arms is smaller than the second plate length of the second plate portion farthest from the plurality of first elastic arms.
